(19) United States
(12) Patent Application Publication
(10) Pub. No.: US 2024/0289284 A1
(43) Pub. Date: Aug. 29, 2024

(54) STORAGE CONTROLLER, STORAGE DEVICE HAVING THE SAME, AND METHOD OF OPERATING THE SAME

(71) Applicant: Samsung Electronics Co., Ltd., Suwon-si (KR)

(72) Inventor: Hanju Lee, Suwon-si (KR)

(73) Assignee: Samsung Electronics Co., Ltd., Suwon-si (KR)

(21) Appl. No.: 18/382,596

(22) Filed: Oct. 23, 2023

(30) Foreign Application Priority Data
Feb. 23, 2023 (KR) 10-2023-0024176

(51) Int. Cl. G06F 13/16; G06F 11/10; G06F 13/42

(52) U.S. Cl. CPC G06F 13/1668; G06F 11/1068; G06F 13/1621; G06F 13/4221

(57) ABSTRACT

A storage controller includes a host block circuit formed at a first die and configured to communicate with a host device; and a plurality of media block circuits formed at at least one second die and configured to control a plurality of media devices. The plurality of media devices are configured to constitute a plurality of channels. Each of the plurality of media block circuits is connected to a corresponding channel of the plurality of channels. The host block circuit and the plurality of media block circuits are connected with each other through a chiplet interface.

### CROSS-REFERENCE TO RELATED APPLICATIONS

This application claims benefit of priority to Korean Patent Application No. 10-2023-0024176 filed on Feb. 23, 2023 in the Korean Intellectual Property Office, the disclosure of which is incorporated herein by reference in its entirety.

### BACKGROUND

Example embodiments of the present disclosure relate to a storage controller, a storage device having the same, and a method of operating the same.

Generally, yield of a semiconductor may decrease as a die size increases. Yield may be improved by splitting production on small dies. A chiplet technique has been used to overcome performance limitations and high cost of monolithic chips. The chiplet technique may enable combination of heterogeneous chips having different line widths, and may enable application of chips suitable for portions to which high-performance chips are required and low-performance chips are applied. Universal chiplet interconnect express (UCIe) may be an open protocol for providing interconnection of chiplet dies based on the advanced interface bus (AIB). UCIe may support a variety of data rates, widths, bump pitches and channel ranges.

### SUMMARY

An example embodiment of the present disclosure is to provide a storage controller, a storage device having the same, and a method of operating the same.

According to an embodiment of the present disclosure, a storage controller includes a host block circuit formed at a first die and configured to communicate with a host device; and a plurality of media block circuits formed at at least one second die and configured to control a plurality of media devices. The plurality of media devices are configured to constitute a plurality of channels. Each of the plurality of media block circuits is connected to a corresponding channel of the plurality of channels. The host block circuit and the plurality of media block circuits are connected with each other through a chiplet interface.

According to an embodiment of the present disclosure, a storage device includes at least one nonvolatile memory device, and a controller configured to control the at least one nonvolatile memory device. The controller includes a host interface circuit formed at a first die and connected to a host device, and a nonvolatile memory interface circuit formed at a second die and connected to the at least one nonvolatile memory device. The host interface circuit formed at the first die and the nonvolatile memory interface circuit formed at the second die are configured to communicate with each other using a chiplet interface.

According to an embodiment of the present disclosure, a method of operating a storage device includes receiving a write request from a host device by a host interface circuit formed at a first die, transmitting the write request to a nonvolatile memory interface circuit formed at a second die using a chiplet interface by the host interface circuit, and outputting a program command corresponding to the write request to at least one nonvolatile memory device by the nonvolatile memory interface circuit.

According to an embodiment of the present disclosure, a method of operating a storage device includes receiving a read request from a host device by a host interface circuit formed at a first die, transmitting the read request to a nonvolatile memory interface circuit formed at a second die using a chiplet interface by the host interface circuit, outputting a read command corresponding to the read request to at least one nonvolatile memory device by the nonvolatile memory interface circuit, receiving read data from the at least one nonvolatile memory device by the nonvolatile memory interface circuit, transmitting the read data to the host interface circuit using the chiplet interface by the nonvolatile memory interface circuit, and outputting the read data to the host device by the host interface circuit.

According to an embodiment of the present disclosure, a method of manufacturing a storage controller includes manufacturing a host block circuit at a first silicon substrate, manufacturing a plurality of media block circuits at a second silicon substrate, disposing the first silicon substrate and the second silicon substrate on a package board, and connecting each of the host block circuit to the plurality of media block circuits using a Universal Chiplet Interconnect Express (UCIe) interface on the package board.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a storage controller according to an example embodiment of the present disclosure;

FIGS. 2A, 2B, 2C, 2D and 2E are diagrams illustrating various examples of a storage controller according to an example embodiment of the present disclosure;

FIG. 3 is a diagram illustrating a host system according to an example embodiment of the present disclosure;

FIG. 4 is a flowchart illustrating a write operation of a storage device according to an example embodiment of the present disclosure;

FIG. 5 is a flowchart illustrating a read operation of a storage device according to an example embodiment of the present disclosure;

FIG. 6 is a ladder diagram illustrating a write operation of a host system according to an example embodiment of the present disclosure;

FIG. 7 is a ladder diagram illustrating a read operation of a host system according to an example embodiment of the present disclosure;

FIG. 8 is a diagram illustrating a storage device according to an example embodiment of the present disclosure;

FIG. 9 is a diagram illustrating a storage device according to an example embodiment of the present disclosure;

FIG. 10 is a diagram illustrating a controller package according to an example embodiment of the present disclosure;

FIG. 11 is a flowchart illustrating a method of manufacturing a storage controller according to an example embodiment of the present disclosure; and

FIG. 12 is a flowchart illustrating a data center to which a memory device according to an example embodiment of the present disclosure.

### DETAILED DESCRIPTION

Hereinafter, embodiments of the present disclosure will be described below with reference to the accompanying drawings.

Host and flash interfaces are demanding higher bandwidths, leading to increased performance and capacity in storage devices. Additionally, customer requirements from data centers and other sources are becoming increasingly diverse and complex. As a result, the size of the controller for managing storage devices is gradually growing, and the time required for back-end operations is exponentially increasing. This can have a detrimental impact on silicon yield of fabricating a system-on-chip (SoC) device which includes various functions on a single die. The present invention addresses these challenges by utilizing chiplet technology in which a modular semiconductor design of a host block and a media block is allowed. This approach reduces the time required for back-end operations, resolves yield issues, and enhances the flexibility of storage devices.

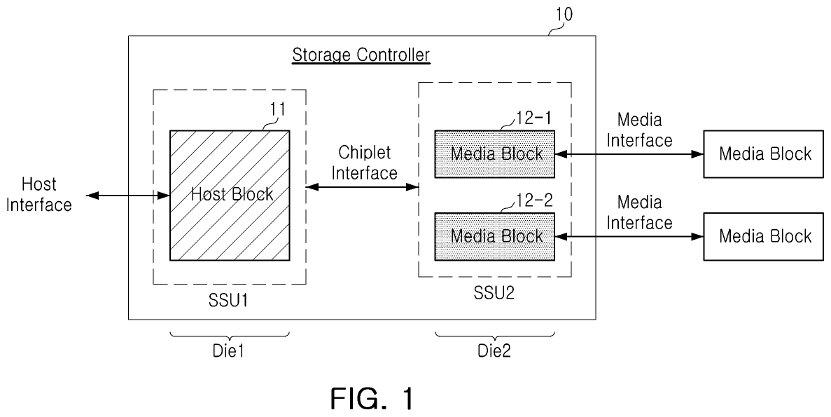

FIG. 1 is a diagram illustrating a storage controller 10 according to an example embodiment. Referring to FIG. 1, the storage controller 10 may include a host block circuit 11, a first media block circuit 12-1 and a second media block circuit 12-2.

The host block circuit 11 may be implemented to communicate with an external host device through a host interface. The host interface may be implemented as an interface of a storage device, such as a peripheral component interconnect express (PCIe), non-volatile memory express (NVMe), serial attached SCSI (SAS), small computer system interface (SCSI), SCSI express (SCSIe), serial advanced technology attachment (SATA), SATA express (SATAe), computer express link (CXL) and Gen-Z. In an example embodiment, the host block circuit 11 may be formed on a first die SSU1. In some embodiment, the first die SSU1 may be a silicon substrate, a silicon-germanium substrate, or a compound semiconductor substrate. The first die SSU1 may also be referred to as a first sub-silicon substrate (i.e., a first silicon substrate).

Each of the first and second media block circuits 12-1 and 12-2 may be implemented to communicate with a corresponding media device through a media interface. The media interface may be implemented as an interface of a memory device such as a NAND interface and a NOR interface. In some embodiments, the corresponding media device may include nonvolatile memory devices such as a NAND flash memory device, a NOR flash memory device, a phase change RAM (PRAM) device, a magnetoresistive RAM (MRAM) device, a spin-transfer torque magnetic random-access memory (STT-MRAM) device, and a ferroelectric RAM (FRAM) or resistive RAM (RRAM) device. In an example embodiment, the first and second media block circuits 12-1 and 12-2 may be formed at a second die SSU2. In some embodiments, each of the first and second media block circuits 12-1 and 12-1 may include a nonvolatile memory controller. In some embodiment, the second die SSU2 may be a silicon substrate, a silicon-germanium substrate, or a compound semiconductor substrate. The second die SSU2 may also be referred to as a second sub-silicon substrate (i.e., a second silicon substrate). Hereinafter, for the simplicity of description, it is assumed that the first and second dies SSU1 and SSU2 are silicon dies. In some embodiments, a plurality of media devices may be configured to constitute a plurality of channels including a first channel CH1 and a second channel CH2. For example, in each separate channel, each media block circuit may communicate with a corresponding media device. As a number of channels increases, the bandwidth between the storage controller 10 and the media devices also increases.

The host block circuit 11 and the media block circuits 12-1 and 12-2 may be connected with each other through a chiplet interface. For example, the sub-silicon substrates SSU1 and SSU2 of the storage controller 10 may communicate with each other according to the chiplet interface. In an example embodiment, the chiplet interface may include a universal chiplet interconnect express (UCIe) interface.

In a general storage controller, an entire path may be implemented on a single silicon substrate from a host interface to a media interface in an SoC device, whereas, in the storage controller 10 according to the example embodiment, a host block circuit 11 and media block circuits 12-1 and 12-2 may be individually fabricated at separated silicon substrates or silicon dies, and may be attached onto a circuit board of the storage controller 10. For example, the storage controller 10 may be referred to as System-on-Package (SoP). Accordingly, the time for developing the storage controller 10 may be reduced and process difficulty may be reduced compared to fabricating the host block circuit 11 and the media block circuits 12-1 and 12-2 at a single silicon substrate (or at a single silicon die).

The storage controller 10 according to an embodiment of the present invention may be used with various host devices and media devices, and it can be implemented by selecting different processes based on the required technical level of the sub-silicon substrate. In particular, the storage controller 10 allows the production of customer-specific controllers in a short period of time with minimal effort by modifying only certain sub-silicon substrates.

The storage controller in the example embodiment allows flexible configuration of the number of media channels included in the sub-silicon substrate.

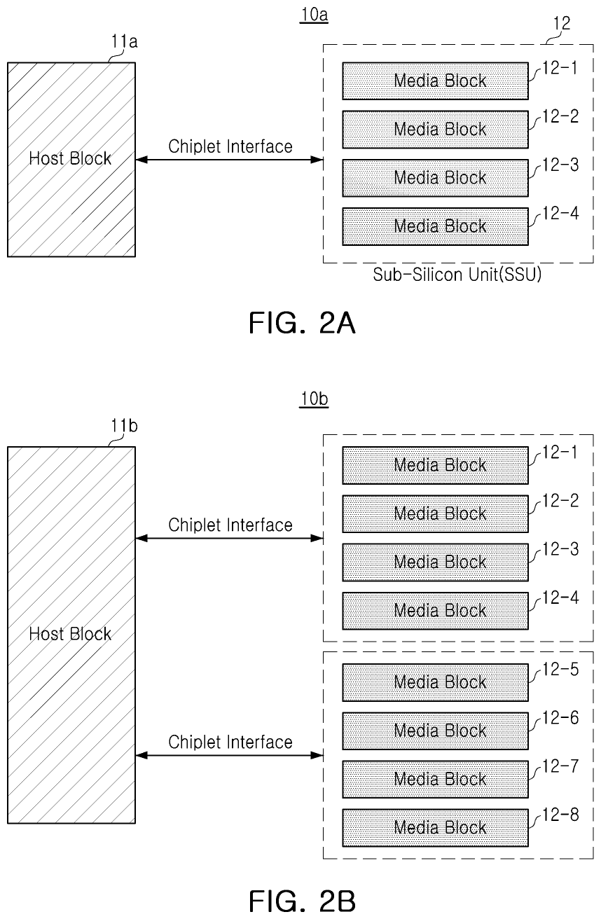

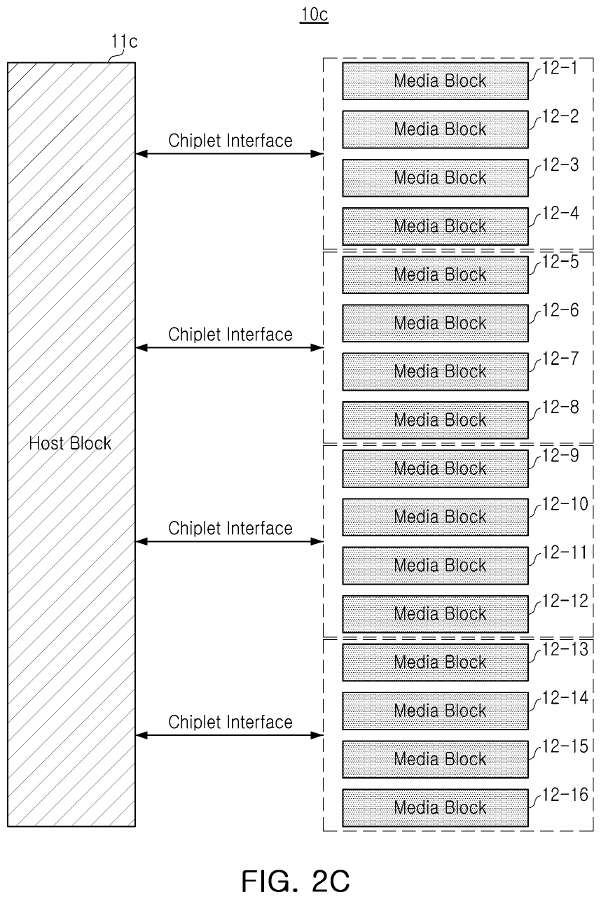

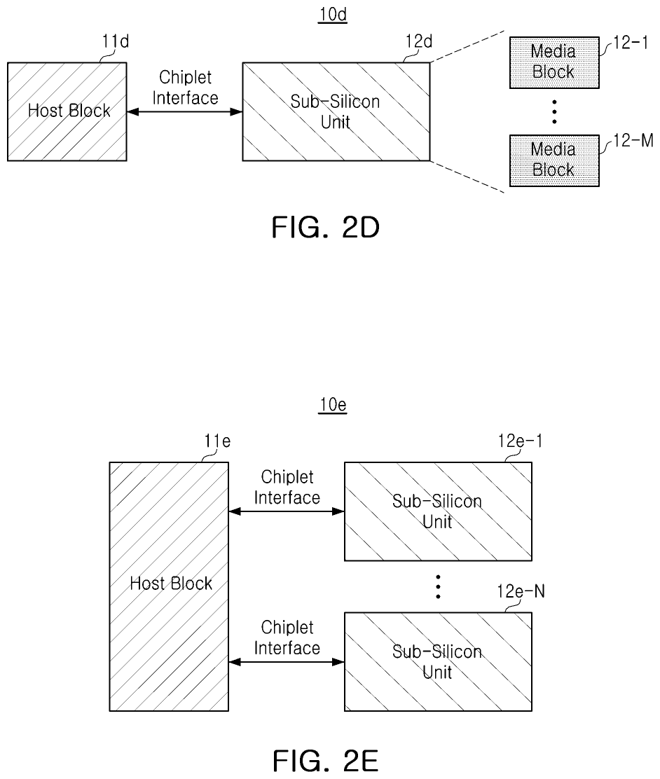

FIGS. 2A, 2B, 2C, 2D and 2E are diagrams illustrating various examples of a storage controller according to an example embodiment.

Referring to FIG. 2A, the storage controller 10a may include a sub-silicon unit 12 connected to the host block circuit 11a through a chiplet interface. The sub-silicon unit 12 may include four media block circuits 12-1 to 12-4. In an example embodiment, the host block circuit 11a may be formed at a first sub-silicon substrate (i.e., a first die). In an example embodiment, the sub-silicon unit 12 may be formed at a second sub-silicon substrate (i.e., a second die).

Referring to FIG. 2B, the storage controller 10b may include eight media block circuits 12-1 to 12-8. In an example embodiment, the host block circuit 11b may be formed at a first sub-silicon substrate. In an example embodiment, four media block circuits 12-1 to 12-4 may be formed at a second sub-silicon substrate, and four media block circuits 12-5 to 12-8 may be formed at a third sub-silicon substrate unit. The host block circuit 11b formed at the first sub-silicon substrate and each of the four media block circuits 12-1 to 12-4 formed at the second sub-silicon substrate may be connected with each other through a chiplet interface, and the host block circuit 11b formed at the first sub-silicon substrate and each of the four media block circuits 12-5 to 12-8 formed at the third sub-silicon substrate may be connected with each other through a chiplet interface.

Referring to FIG. 2C, the storage controller 10c may include 16 media block circuits 12-1 to 12-16. In an example embodiment, the host block circuit 11c may be formed at a first sub-silicon substrate. In an example embodiment, four media block circuits 12-1 to 12-4 may be formed at a second sub-silicon substrate, and four media block circuits 12-5 to 12-8 may be formed at a third sub-silicon substrate. Four media block circuits 12-9 to 12-12 may be formed at a fourth sub-silicon substrate, and four media block circuits 12-13 to 12-16 may be formed at a fifth sub-silicon substrate. The host block circuit 11c formed at the first sub-silicon substrate and each of the four media block circuits 12-1 to 12-4 formed at the second sub-silicon substrate may be connected with each other through a chiplet interface. The host block circuit 11c formed at the first sub-silicon substrate and each of the four media block circuits 12-5 to 12-8 formed at the third sub-silicon substrate may be connected with each other through a chiplet interface. The host block circuit 11c formed at the first sub-silicon substrate and each of the four media block circuits 12-9 to 12-12 formed at the fourth sub-silicon substrate may be connected with each other through a chiplet interface. The host block circuit 11c formed at the first sub-silicon substrate and each of the four media block circuits 12-13 to 12-16 formed at the fifth sub-silicon substrate may be connected with each other through a chiplet interface.

Referring to FIG. 2D, the storage controller 10d may include a host block circuit 11d and a sub-silicon unit 12d including a plurality of media block circuits 12-1 to 12-M (M is an integer of 2 or more). The host block circuit 11d and the sub-silicon unit 12d may communicate with each other through a chiplet interface. In an example embodiment, the host block circuit 11d may be formed at a first silicon die (i.e., a first sub-silicon substrate), and the sub-silicon unit 12d may be formed at a second silicon die (i.e., a second sub-silicon substrate). In some embodiments, the first silicon die and the second silicon die are individual dies that are fabricated by separate fabrication processes. For example, the first silicon die may be fabricated on a first wafer and then tested to determine whether a circuit formed at the first silicon die properly operates, and in a process and test separated from the fabrication/test of the first silicon die, the second silicon die may be prepared. In some embodiments, the first and second silicon dies may be attached to a circuit board of the storage controller 10d or may be separately packaged before being attached to the circuit board of the storage controller 10d.

Referring to FIG. 2E, the storage controller 10d may include a host block circuit 11d and a plurality of sub-silicon units 12e-1 to 12e-N(N is an integer greater than or equal to 2). Each of the sub-silicon units 12e-1 to 12e-N may include at least one media block circuit. In an example embodiment, each of the sub-silicon units 12e-1 to 12e-N may include the same number of media block circuits. In another example embodiment, at least one of the sub-silicon units 12e-1 to 12e-N may include a different number of media block circuits. Each of the host block circuit 11e and a plurality of sub-silicon units 12e-1 to 12e-N may communicate with each other through a chiplet interface. The example embodiment may be applicable to a controller for controlling a nonvolatile memory device.

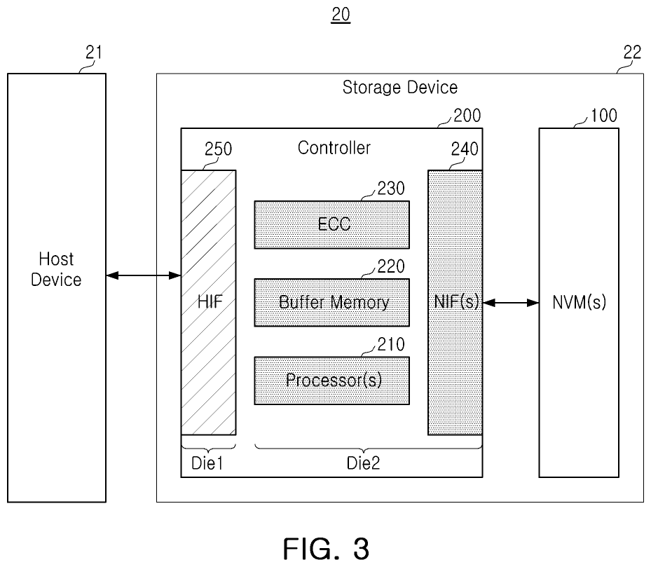

FIG. 3 is a diagram illustrating a host system according to an example embodiment.

The host system 20 may be implemented as a server computer, a personal computer (PC), a desktop computer, a lap-top computer, a workstation computer, a network-attached storage (NAS), a data center, an internet data center (IDC), or a mobile computing device. For example, the mobile computing device may be implemented as a smart phone, a tablet PC, or a mobile internet device (MID).

The host device 21 may be implemented to control a data processing operation (e.g., a write operation or a read operation) of the storage device 22. The host device 21 may include at least one of a central processing unit (CPU), a buffer memory, a memory device, a memory controller, and an interface circuit. The host device 21 may be implemented as an integrated circuit, a motherboard, or a system on chip. In example embodiments, the host device 21 may be implemented as an application processor or a mobile application processor.

The CPU may exchange commands or data with a buffer memory, a memory controller, and an interface circuit through a bus architecture. In an example embodiment, the bus architecture may be implemented as an advanced microcontroller bus architecture (AMBA), AMBA advanced extensible interface (AXI), AMBA advanced high-performance bus (AHB), or advanced interface bus (AIB). The buffer memory may store queues. In an example embodiment, the buffer memory may be implemented as a register or a static random access memory (SRAM). The queue may include a submission queue. The queue may store commands (e.g., a write command or a read command). In an example embodiment, the queue may further include a completion queue. In the completion queue, each entry may correspond to a completed task or operation. For example, the completed tasks may include I/O requests, memory transfers, or other asynchronous operations. When a task is completed, information about the task's status and/or its outcome may be stored as an entry within the completion queue.

The memory device may be implemented as a volatile memory device or a nonvolatile memory device. Here, the volatile memory may be implemented as a random access memory (RAM), SRAM, or dynamic RAM DRAM. The nonvolatile memory may also be implemented as a NAND flash memory, NOR flash memory, phase change RAM (PRAM), magnetoresistive RAM (MRAM), spin-transfer torque magnetic random-access memory (STT-MRAM), ferroelectric RAM (FRAM) or resistive RAM (RRAM). The memory controller may write data to the memory device or may read stored data from the memory device under control of the CPU. In an example embodiment, the memory controller may include functions of a direct memory access (DMA) controller. The interface circuit may be connected to a host interface circuit 250 of the storage device 22 through a predetermined host interface.

The storage device 22 may include at least one nonvolatile memory device 100 and a controller 200. At least one nonvolatile memory device 100 may be implemented to store data. The nonvolatile memory device 100 may be implemented as a NAND flash memory, vertical NAND flash memory, NOR flash memory, resistive random access memory (RRAM), phase-change memory (PRAM), magnetoresistive random access memory (MRAM), ferroelectric random access memory (FRAM), or spin transfer torque random access memory (STT-RAM). Hereinafter, the nonvolatile memory device 100 will be referred to as a vertical NAND flash memory device for ease of description.

The controller 200 may be connected to at least one nonvolatile memory device 100 through a plurality of control pins that transmit control signals (e.g., CLE, ALE, CE(s), WE, RE, etc.). The controller 200 may be implemented to control the nonvolatile memory device 100 using control signals (CLE, ALE, CE(s), WE, RE, etc.). For example, the nonvolatile memory device 100 may perform a program operation/read operation/erase operation by latching a command (CMD) or an address (ADD) at an edge of WE (write enable) signal according to a command latch enable signal (CLE) and an address latch enable signal (ALE). For example, during a read operation, the chip activation signal (CE) may be activated, the CLE may be activated during the command transmission period, the ALE may be activated during the address transmission period, and RE may be toggled in a period in which data is transmitted through a data signal (DQ) line. A data strobe signal (DQS) may be toggled at a frequency corresponding to the data input/output speed. Read data may be sequentially transmitted in synchronization with the DQS.

The controller 200 may be implemented to control overall operations of the storage device 22. The controller 200 may include at least one processor 210, a buffer memory 220, an error correction circuit 230, at least one nonvolatile memory interface circuit 240 NIF, and a host interface circuit 250.

At least one processor 210 may be implemented to control overall operation of the storage device 22. The processor 210 may perform various management such as cache/buffer management, firmware management, garbage collection management, wear leveling management, data deduplication management, read refresh/reclaim management, bad block management, multi-stream management, mapping management between host data and nonvolatile memory, quality of service (QOS) management, system resource allocation management, nonvolatile memory queue management, read level management, erase/program management, hot/cold data management, power loss protection management, dynamic thermal management, initialization management, and redundant array of inexpensive disk (RAID). These management operations may be implemented in hardware/firmware/software.

The buffer memory 220 may be implemented to temporarily store data necessary for operation of the storage device 22. For example, the buffer memory 220 may temporarily store data to be written to the nonvolatile memory device 100 or data read from the nonvolatile memory device 100. In an example embodiment, the buffer memory 220 may be configured to be included in the controller 200. In another example embodiment, the buffer memory 220 may be disposed externally of the controller 200. The buffer memory 220 may be implemented as a volatile memory (e.g., static random access memory (SRAM), dynamic RAM DRAM, synchronous RAM (SDRAM), or the like) or a nonvolatile memory (flash memory, phase-change RAM (PRAM), magneto-resistive RAM (MRAM), resistive RAM (ReRAM), ferro-electric RAM (FRAM), or the like).

The error correction circuit 230 may be implemented to generate an error correction code ECC during a program operation and may recover data using the error correction code during a read operation. For example, the error correction circuit 230 may generate an error correction code ECC for correcting a fail bit or an error bit of data received from the nonvolatile memory device 100. The error correction circuit 230 may form data to which parity bits are added by performing error correction encoding of data provided to the nonvolatile memory device 100. The parity bits may be stored in the nonvolatile memory device 100.

The error correction circuit 230 may perform error correction decoding on data output from the nonvolatile memory device 100. The error correction circuit 230 may correct errors using various error correction codes. The error correction circuit 230 may correct an error using a low density parity check (LDPC) code, BCH code, turbo code, Reed-Solomon code, convolution code, recursive systematic code (RSC), or coded modulation such as trellis-coded modulation (TCM) and block coded modulation (BCM). When error correction is determined as impossible in the error correction circuit 230, a read retry operation may be performed.

At least one nonvolatile memory interface circuit 240 may exchange data through a plurality of pins described above in at least one nonvolatile memory device 100. The nonvolatile memory interface circuit 240 may transmit data to be written in the nonvolatile memory device 100 to the nonvolatile memory 100 or may receive data read from the nonvolatile memory device 100. The nonvolatile memory interface circuit 240 may be implemented to comply with standard protocols such as JEDEC Toggle and ONFI.

The host interface circuit 250 may be implemented to provide interface functions with the host device 21. The host interface circuit 250 may be implemented to transmit packets to and receive packets from a host. A packet transmitted from the host to the host interface circuit 250 may include a command or data to be written to the nonvolatile memory device 100. A packet transmitted from the host interface circuit 250 to the host may include a response to a command or data read from the nonvolatile memory device 100.

In an example embodiment, the host interface circuit 250 may be formed at a first die, and the other components 210, 220, 230, and 240 may be formed at a second die. The first die and the second die may be implemented to communicate with each other through a chiplet interface. Each of the other components 210, 220, 230, and 240 may communicate with the host interface circuit 250 using a chiplet interface. For example, the other components 210, 220, 230, and 240 may be connected to a system bus SB supporting a chiplet interface. For example, the system bus SB may be compatible with the chiplet interface. In some embodiments, the system bus may be an advanced interface bus (AIB).

The controller 200 may further include an encryption device to improve information protection. The encryption device may perform at least one of an encryption operation and a decryption operation on data input to the controller 200 using a symmetric-key algorithm. The encryption device may perform encryption and decryption of data using advanced encryption standard (AES) algorithm. The encryption device may include an encryption module and a decryption module. In an example embodiment, an encryption device may be implemented in hardware/software/firmware. The encryption device may perform a self-encryption disk (SED) function or a trusted computing group (TCG) security function. The SED function may store encrypted data in the nonvolatile memory device 100 using an encryption algorithm or may decrypt encrypted data from the nonvolatile memory device 100. The encryption/decryption operations may be performed using an internally generated encryption key. The TCG security function may provide a mechanism enabling access control to user data of the nonvolatile memory device 100. For example, the TCG security function may perform an authentication procedure between an external device and the nonvolatile memory device 100. In an example embodiment, the SED function or the TCG security function may be optionally selected.

In the controller 200 illustrated in FIG. 3, the host interface circuit 250 and the other components 210, 220, 230, and 240 may be formed at individual dies. However, an example embodiment thereof is not limited thereto, and components in the controller may be formed at a sub-silicon substrate in various combinations.

The storage device 22 according to the example embodiment may include a controller 200 which may easily and inexpensively implement an internal configuration by applying the chiplet technique, such that the storage device 22 may be applied to various host devices 21 and various types of nonvolatile memory devices 100.

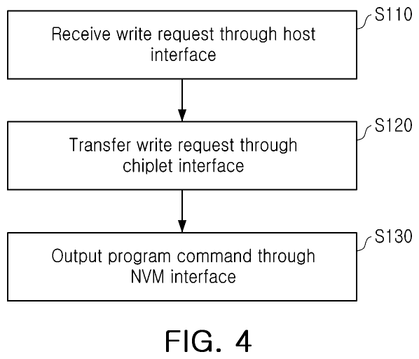

FIG. 4 is a flowchart illustrating a write operation of a storage device 22 according to an example embodiment. Referring to FIGS. 3 and 4, the storage device 22 may perform a write operation as below.

The host interface circuit 250 of the storage device 22 may receive a write request from the host device 21 through the host interface (S110). The host interface circuit 250 may transmit the received write request to the nonvolatile memory interface circuit 240 through the chiplet interface (S120). The nonvolatile memory interface circuit 240 may output a program command to the nonvolatile memory device 100 through the nonvolatile memory interface.

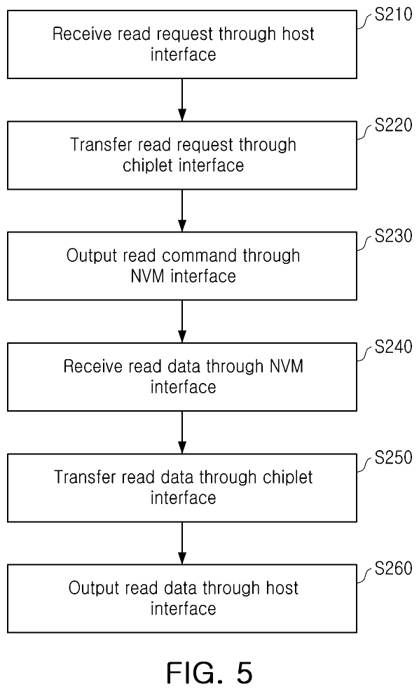

FIG. 5 is a flowchart illustrating a read operation of a storage device 22 according to an example embodiment. Referring to FIGS. 3 and 5, the storage device 22 may perform a read operation as below.

The host interface circuit 250 of the storage device 22 may receive a read request from the host device 21 through the host interface (S210). The host interface circuit 250 may transmit a read request to the nonvolatile memory interface circuit 240 through a chiplet interface (S220). The nonvolatile memory interface circuit 240 may issue a read command corresponding to the received read request and may output the read command to the nonvolatile memory device 100 through the nonvolatile interface (S230). The nonvolatile memory interface circuit 240 may receive read data corresponding to the read command from the nonvolatile memory device 100 through the nonvolatile interface (S240). The nonvolatile memory interface circuit 240 may transmit read data to the host interface circuit 250 through a chiplet interface (S250). The host interface circuit 250 may output read data to the host device 21 through the host interface (S260).

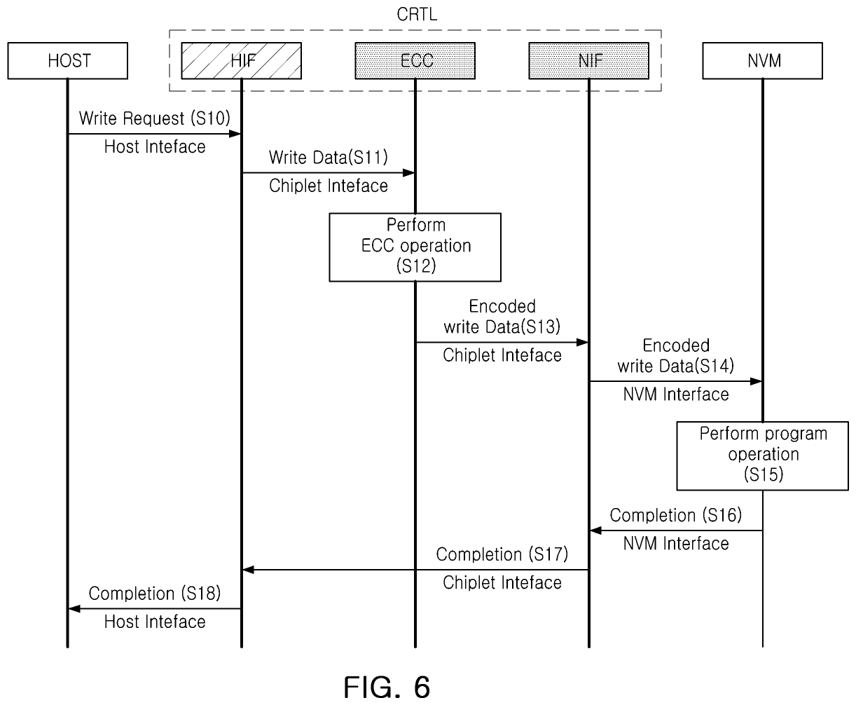

FIG. 6 is a ladder diagram illustrating a write operation of a host system according to an example embodiment. In FIG. 6, the controller CRTL may include a host interface circuit HIF, an error correction circuit ECC, and a nonvolatile memory interface circuit NIF. The error correction circuit ECC and the nonvolatile memory interface circuit NIF may be connected to the system bus and may communicate through a chiplet interface.

The host device may transmit a write request to the host interface circuit HIF through a host interface (S10). The write request may include write data and an address to store the write data. The host interface circuit HIF of the controller CRTL may transmit write data to the error correction circuit ECC through the chiplet interface (S11). The error correction circuit ECC may perform an ECC encoding operation of calculating an error correction code value for write data (S12). The error correction circuit ECC may transmit encoded write data to the nonvolatile memory interface circuit NIF through the chiplet interface (S13). The nonvolatile memory interface circuit NIF may output the program command to the nonvolatile memory device NVM along with the encoded write data through the nonvolatile memory interface (S14).

The nonvolatile memory device NVM may perform a program operation on encoded write data in response to a program command (S15). Thereafter, the nonvolatile memory device NVM may output the program write completion to the nonvolatile memory interface circuit NIF through the nonvolatile memory interface (S16). The nonvolatile memory interface circuit NIF may output write completion information to the host interface circuit HIF through a chiplet interface (S17). The host interface circuit HIF may output write completion information to the host device through the host interface (S18).

In FIG. 6, the error correction circuit ECC may be disposed at a media sub-silicon substrate (i.e., the second die Die2 at which the nonvolatile memory interface circuit 240 of FIG. 3 is formed, for example). However, an example embodiment thereof is not limited thereto. For example, the error correction circuit ECC may be disposed at a host sub-silicon substrate (i.e., the first die Die1 at which the host interface circuit 250 of FIG. 3 is formed, for example).

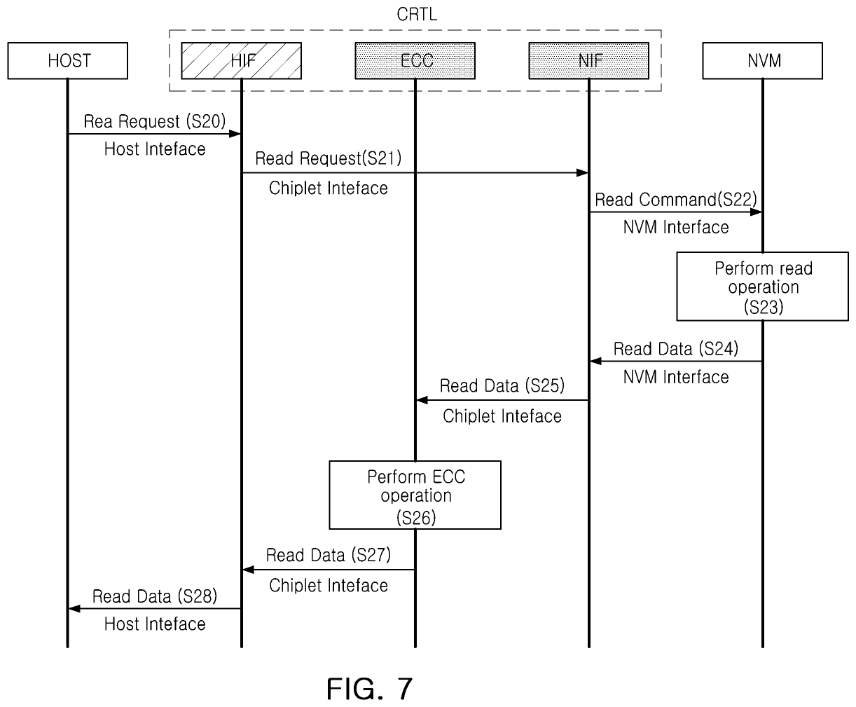

FIG. 7 is a ladder diagram illustrating a read operation of a host system according to an example embodiment. Referring to FIG. 7, the read operation of the host system may be performed as below.

The host device may transmit a read request to the host interface circuit HIF through a host interface (S20). The read request may include an address corresponding to read data. The host interface circuit HIF of the controller CRTL may transmit a read request to the nonvolatile memory interface circuit NIF through the chiplet interface (S21). The nonvolatile memory interface circuit NIF may output a read command to the nonvolatile memory device NVM through the nonvolatile memory interface (S22).

The nonvolatile memory device NVM may perform a read operation in response to a read command (S23). Thereafter, the nonvolatile memory device NVM may output read data to the nonvolatile memory interface circuit NIF through the nonvolatile memory interface (S24). The nonvolatile memory interface circuit NIF may output read data to the error correction circuit ECC through a chiplet interface (S25). The error correction circuit ECC may perform an error correction operation on read data (S26). The error correction circuit ECC may output error corrected read data to the host interface circuit HIF through the chiplet interface (S27). The host interface circuit HIF may output read data corresponding to the read request to the host device through the host interface (S28).

In FIG. 7, an error correction circuit ECC may be disposed at a media sub-silicon substrate (i.e., the second die Die2 at which the nonvolatile memory interface circuit 240 of FIG. 3 is formed, for example). However, an example embodiment thereof is not limited thereto. For example, the error correction circuit ECC may be disposed at a host sub-silicon substrate (i.e., the first die Die1 at which the host interface circuit 250 of FIG. 3 is formed).

In some embodiments, a storage device according to an example embodiment may include a volatile memory device disposed externally of the controller.

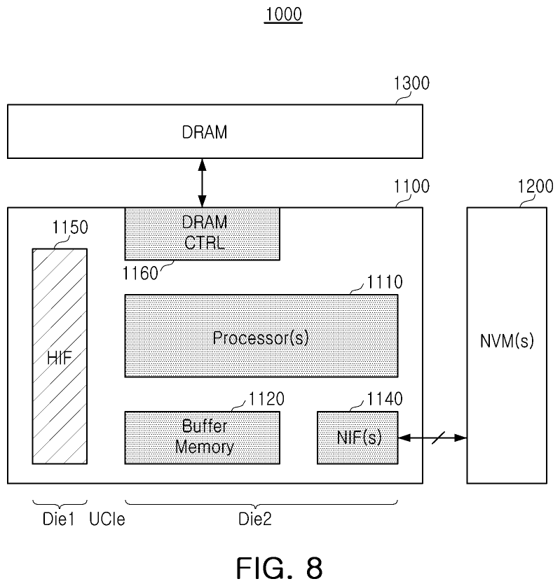

FIG. 8 is a diagram illustrating a storage device 1000 according to an example embodiment. Referring to FIG. 8, the storage device 1000 may include a controller 1100, at least one nonvolatile memory device 1200, and a volatile memory device 1300.

The controller 1100 may include at least one processor 1110, a buffer memory 1120, at least one nonvolatile memory interface circuit 1140, a host interface circuit 1150, and a volatile memory controller 1160.

In an example embodiment, the host interface circuit 1150 may be formed at a first die. In an example embodiment, the processor 1110, the buffer memory 1120, the nonvolatile memory interface circuit 1140, and the volatile memory controller 1160 may be formed at a second die. The first die and the second die may be different sub-silicon substrates (i.e., individual sub-silicon substrates). In an example embodiment, the first die and the second die may be connected to each other according to a chiplet interface (e.g., UCIe).

In an example embodiment, at least one nonvolatile memory device 1200 may be implemented in a stacked package form. For example, at least one nonvolatile memory device 1200 may include stacked nonvolatile memory chips corresponding to the number of a plurality of channels and a buffer chip connected to the corresponding nonvolatile memory chip through a plurality of internal channels. The buffer chip may be connected to at least one nonvolatile memory interface circuit 1140 through a plurality of channels.

In an example embodiment, the volatile memory device 1300 may be configured to be stacked on the controller 1100. In some embodiments, at least one volatile memory device such as DRAM may be stacked on the controller 1100 to constitute a high bandwidth memory (HBM) device. For example, at least one DRAM die may be stacked on the volatile memory controller 1160 such as a DRAM controller to form an HBM device.

The buffer memory 1120 illustrated in FIG. 8 may be disposed at the second die Die2. However, an example embodiment thereof is not limited thereto. For example, the buffer memory may be disposed at the first die Die1.

In the controller 1100 illustrated in FIG. 8, internal components may be disposed on two sub-silicon substrates. However, an example embodiment thereof is not limited thereto.

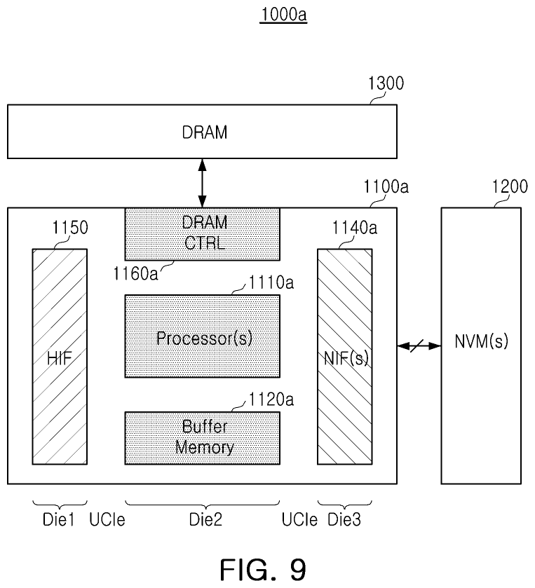

FIG. 9 is a diagram illustrating a storage device 1000a according to an example embodiment. Referring to FIG. 9, the storage device 1000a may include a controller 1100a in which internal components are disposed on three dies as compared to the example illustrated in FIG. 8.

The controller 1100a may include a host interface circuit 1150 formed at a first die Die1, a processor 1110a formed at a second die Die2, a buffer memory 1120a, a volatile memory controller 1160a, and a nonvolatile memory interface circuit 1140a formed at a third die Die3. The first die Die1, the second die Die2, and the third die Die3 may be implemented as different sub-silicon substrates (i.e., individual silicon dies). In an example embodiment, the first die Die1, the second die Die2, and the third die Die3 may communicate with each other through a chiplet interface (e.g., UCIe).

In FIG. 9, the processor 1110a, the buffer memory 1120a, and the volatile memory controller 1160a may be disposed at the second die Die2. However, an example embodiment thereof is not limited thereto. For example, the processor, the buffer memory, and the volatile memory controller may be disposed at the first die Die1 or at the third die Die3. The For example, the processor, the buffer memory, and the volatile memory controller may be disposed in various combinations at two or more dies among the first die Die1, the second die Die2, and the third die Die3.

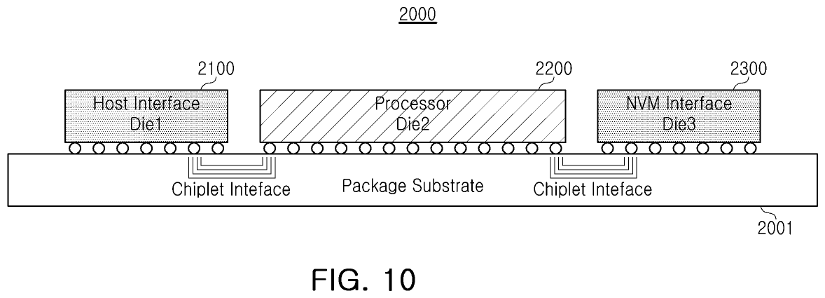

FIG. 10 is a diagram illustrating a controller package 2000 according to an example embodiment. Referring to FIG. 10, the controller package 2000 may include a package board 2001, a first die 2100, a second die 2200, and a third die 2300.

The first die 2100 may include a host interface circuit. In an example embodiment, the first die 2100 may be configured as a sub-silicon substrate disposed on the package board 2001. The second die 2200 may include a processor. In an example embodiment, the second die 2200 may be configured as a sub-silicon substrate disposed on the package board 2001. The third die 2300 may include a nonvolatile memory interface circuit. In an example embodiment, the third die 2300 may be configured as a sub-silicon substrate disposed on the package board 2001.

In an example embodiment, the first die 2100 and the second die 2200 may be connected using a chiplet interface. In an example embodiment, the second die 2200 and the third die 2300 may be connected using another chiplet interface. The two chiplet interfaces may be implemented using a universal chiplet interconnect express (UCIe) interface.

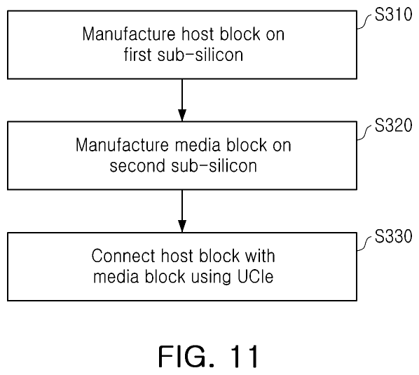

FIG. 11 is a flowchart illustrating a method of manufacturing a storage controller according to an example embodiment. Referring to FIG. 11, operations of manufacturing the storage controller may be performed as below. A host block circuit (e.g., the host block circuit 11 in FIG. 1) may be manufactured at a first sub-silicon substrate in a first process environment (S310). A media block circuit (e.g., the media block circuits 12-1 and 12-2 in FIG. 1) may be manufactured at a second sub-silicon substrate in a second process environment. The first sub-silicon substrate and the second sub-silicon substrate that are fabricated in different process environments may be connected with each other using a chiplet interface on a package board (e.g., the package board 2001 in FIG. 10). In an example embodiment, the chiplet interface may be a universal chiplet interconnect express (UCIe) interface.

In an example embodiment, the host block circuit may include a host interface circuit, and each of the plurality of media block circuits may include a nonvolatile memory interface circuit connected to a channel. In an example embodiment, a first sub-silicon substrate and a second sub-silicon substrate may be connected to the package board using the UCIe interface. In an example embodiment, a first sub-silicon substrate and a plurality of second sub-silicon substrates may be connected to a package board using the UCIe interface. In an example embodiment, at least one processor may be manufactured on a third sub-silicon substrate, and the third sub-silicon substrate and the first and second sub-silicon substrates may be connected to the package board using the UCIe interface.

The storage device in the example embodiment may be applicable to a data server system.

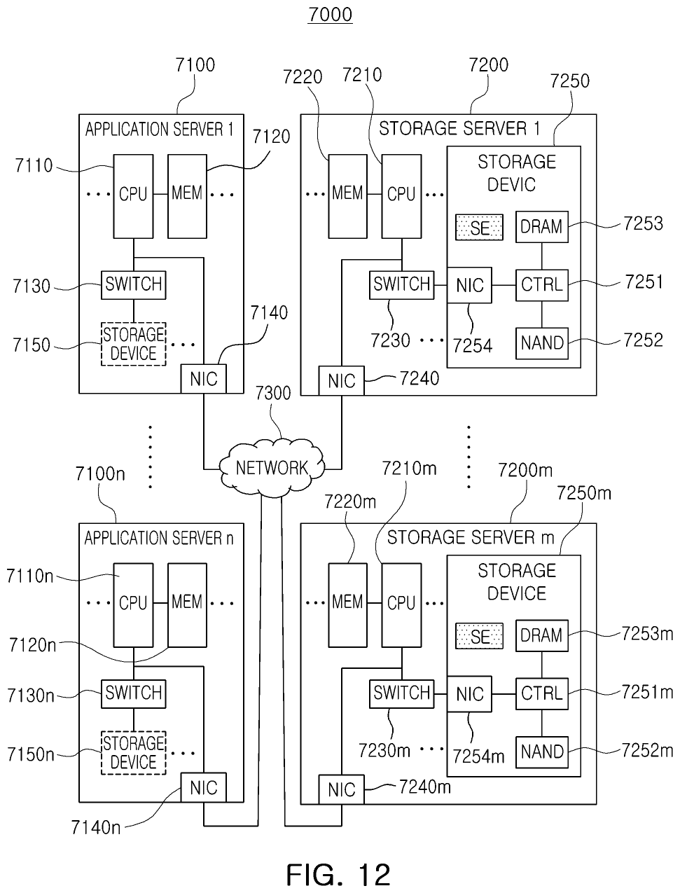

FIG. 12 illustrates a data center according to an example embodiment. Referring to FIG. 12, a data center 7000 may include application servers 7100 to 7100n and storage servers 7200 to 7200m. The number of application servers 7100 to 7100n and the number of storage servers 7200 to 7200m may be variously selected in example embodiments, and the number of application servers 7100 to 7100n may be different from the number of storage servers 7200 to 7200m.

The application server 7100 or the storage server 7200 may include at least one of processors 7110 and 7210 and memory 7120 and 7220. For example, in the storage server 7200, the processor 7210 may control overall operation of the storage server 7200, may access the memory 7220, and may execute commands or data loaded in the memory 7220. The memory 7220 may be implemented as double data rate synchronous DRAM (SDRAM), high bandwidth memory (HBM), hybrid memory cube (HMC), dual in-line memory module (DIMM), Optane DIMM or non-volatile DIMM (NVMDIMM). In example embodiments, the number of processors 7210 and the number of memories 7220 included in the storage server 7200 may be variously selected. In an example embodiment, the processor 7210 and the memory 7220 may provide a processor-memory pair. In the example embodiment, the number of processors 7210 may be different from the number of memories 7220. The processor 7210 may include a single core processor or a multi-core processor. The above description of the storage server 7200 may be similarly applied to the application server 7100. In example embodiments, the storage device 7150 may be omitted from the application server 7100. The storage server 7200 may include at least one storage device 7250. The number of storage devices 7250 included in the storage server 7200 may be variously selected in example embodiments.

The application servers 7100 to 7100n and the storage servers 7200 to 7200m may communicate with each other through a network 7300. The network 7300 may be implemented using fiber channel (FC) or Ethernet. The FC may be a medium used for relatively high-speed data transmission, and an optical switch providing high performance/high availability may be used. Depending on an access method of the network 7300, the storage servers 7200 to 7200m may be provided as file storage media, block storage media, or object storage media.

In an example embodiment, the network 7300 may be implemented as a storage-only network, such as a storage area network (SAN). For example, the SAN may be implemented as an FC-SAN using an FC network and implemented according to FC Protocol (FCP). For another example, the SAN may be implemented as an IP-SAN using a TCP/IP network and implemented according to the iSCSI (SCSI over TCP/IP or Internet SCSI) protocol. In another example embodiment, the network 7300 may be a generic network such as a TCP/IP network. For example, the network 7300 may be implemented according to protocols such as FC over Ethernet (FCOE), network attached storage (NAS), and NVMe over fabrics (NVMe-oF). The description of the application server 7100 may be applied to other application servers 7100n, and the description of the storage server 7200 may also be applied to other storage servers 7200m.

The application server 7100 may store data requested by a user or a client to be stored in one of the storage servers 7200 to 7200m through the network 7300. The application server 7100 may obtain data requested by a user or a client to read from one of the storage servers 7200 to 7200m through the network 7300. For example, the application server 7100 may be implemented as a web server or a database management system (DBMS).

The application server 7100 may access a memory 7120n or a storage device 7150n included in another application server 7100n through the network 7300, or may access the memories 7220 to 7220m or the storage devices 7250 to 7250m included in the storage servers 7200 to 7200m through the network 7300. Accordingly, the application server 7100 may perform various operations on data stored in the application servers 7100 to 7100n or the storage servers 7200 to 7200m. For example, the application server 7100 may execute a command to move or copy data between the application servers 7100 to 7100n or the storage servers 7200 to 7200m. The data may move from the storage device 7250 to 7250m of the storage servers 7200 to 7200m to the memories 7220 to 7220m of the storage servers 7200 to 7200m, or may directly move to the memories 7120 to 7120n of application servers 7100 to 7100n. The data moving through the network 7300 may be encrypted data for security or privacy.

Referring to the storage server 7200 as an example, an interface 7254 may provide a physical connection between the processor 7210 and the controller 7251 and a physical connection between a network interface 7240 and the controller 7251. For example, the interface 7254 may be implemented by a direct attached storage (DAS) method of directly connecting the storage device 7250 to the processor 7210 with a dedicated cable. For example, the interface 7254 may be implemented by various interface methods such as advanced technology attachment (ATA), serial ATA (SATA), external SATA (e-SATA), small computer small interface (SCSI), serial attached SCSI (SAS), peripheral component interconnection (PCI), PCI express (PCIe), NVMe (NVM express), IEEE 1394, universal serial bus (USB), secure digital (SD) card, multi-media card (MMC), embedded multi-media card (eMMC), universal flash storage (UFS), embedded universal (eUFS) flash Storage), and compact flash (CF) card interface

The storage server 7200 may further include a switch 7230 and the network interface 7240. The switch 7230 may selectively connect the processor 7210 to the storage device 7250 or may selectively connect the network interface 7240 to the storage device 7250 under control of the processor 7210.

In the example embodiment, the network interface 7240 may include a network interface card and a network adapter. The network interface 7240 may be connected to the network 7300 through a wired interface, a wireless interface, a Bluetooth interface, or an optical interface. The network interface 7240 may include an internal memory, a digital signal processor (DSP), and a host bus interface, and may be connected to the processor 7210 or the switch 7230 through a host bus interface. The host bus interface may be implemented as one of the examples of the interface 7254 described above. In the example embodiment, the network interface 7240 may be integrated with at least one of the processor 7210, the switch 7230, and the storage device 7250.

In the storage server 7200 to 7200m or the application server 7100 to 7100n, the processor may transmit a command to the storage devices 7150 to 7150n and 7250 to 7250m or the memories 7120 to 7120n and 7220 to 7220m and may program or read the data. The data may be error corrected data through an error correction code (ECC) engine. The data may be obtained by performing data bus inversion (DBI) or data masking (DM) processing, and may include cyclic redundancy code (CRC) information. The data may be encrypted data for security or privacy.

The storage device 7150 to 7150m and 7250 to 7250m may transmit a control signal and a command/address signal to the NAND flash memory device 7252 to 7252m in response to a read command received from the processor. Accordingly, when data is read from the NAND flash memory device 7252 to 7252m, a read enable (RE) signal may be input as a data output control signal and may output data to the DQ bus. A data strobe (DQS) may be generated using the RE signal. A command signal and an address signal may be latched in the page buffer according to a rising edge or a falling edge of the write enable (WE) signal.

In an example embodiment, the storage devices 7150 to 7150m and 7250 to 7250m may include a controller using a chiplet technique as described in FIGS. 1 to 11.

The controller 7251 may control overall operation of the storage device 7250. In an example embodiment, the controller 7251 may include a static random access memory (SRAM). The controller 7251 may write data to the NAND flash memory device 7252 in response to a write command, or may read data from the NAND flash memory device 7252 in response to a read command. For example, a write command or a read command may be provided from the processor 7210 in the storage server 7200, the processor 7210m in another storage server 7200m, or the processor 7110 or 7110n in the application server 7100 or 7100n. The DRAM 7253 may temporarily store (buffer) data to be written to the NAND flash memory device 7252 or data read from the NAND flash memory device 7252. The DRAM 7253 may store meta data. The meta data may be user data or data generated by the controller 7251 to manage the NAND flash memory device 7252.

Generally, as the size of the silicon die increases, the defect rate may exponentially increase. The size of the silicon die has also increased due to the rising performance requirements for storage devices and the diverse and complex demands of customers. Consequently, the time required to go through the back-end flow in the design process stage may exponentially increase, along with an increase in design difficulty. Additionally, with changes in PCIe generations (Gen3→4→5→ . . . ) and NAND generations (Toggle 3.0→4.0→5.0→ . . . ), as well as advancements in micro-processing, it may not be possible to utilize a control silicon board from a previous generation. For example, as PCIe generations evolve (from Gen3 to Gen4 to Gen5 and beyond) and NAND generations progress (from Toggle 3.0 to 4.0 to 5.0 and beyond), along with continuous micro-processing advancements, the compatibility of a silicon die from a previous generation may become impractical. Therefore, for each generation, a new silicon die for a controller demands entirely new design. The storage controller according to the example embodiment may divide a silicon board into two main portions: a host block in charge of a host interface and a media block in charge of a media interface. For example, the storage controller in the example embodiment may divide a silicon board into a first sub-silicon substrate having a host block and a second sub-silicon substrate having a media block. The first sub-silicon substrate and the second sub-silicon substrate may be connected with each other according to a chiplet interface.

The storage controller in the example embodiment may be utilized for various hosts and media, and different processes may be applied based on the desirable technical level of the sub-silicon substrate. For example, a storage board may be produced by manufacturing a sub-silicon substrate for a microprocessor as a high-speed host block, and using a sub-silicon substrate from the previous generation without switching the NAND generation for a media block. Similarly, when there is a need to switch the NAND generation and change the media block, a storage controller may be produced by manufacturing a sub-silicon substrate exclusively for the media block.

In the example embodiment, it is possible to manufacture a storage controller specialized for each customer in a short period of time with reduced efforts by modifying only a portion of the sub-silicon substrates. For example, by manufacturing various media block sub-silicon substrates on a host block sub-silicon substrate that has a multi-physical function NVMe device (MFND) function, an MFND controller may be produced.

In the storage controller according to the example embodiment, the types of media and the number of channels may be flexibly configured. For instance, a sub-silicon substrate with NAND 4-channel may be manufactured. When manufacturing a 16-channel solid state drive (SSD), a storage controller may be produced by combining 1 host block sub-silicon substrate and 4 media block sub-silicon substrates. The sub-silicon substrates can communicate with each other using a chiplet interface (e.g., UCIe).

A storage controller, a storage device having the same and an operating method thereof according to the present invention may utilize a chiplet technology to separate/design the controller into a host block and a media block(s). The storage controller, the storage device, and the method may reduce the time required for back-end work in controller manufacturing, may address yield issues, and may enhance the flexibility of the storage device.

While the example embodiments have been illustrated and described above, it will be configured as apparent to those skilled in the art that modifications and variations could be made without departing from the scope of the present disclosure as defined by the appended claims.

1. A storage controller comprising:
a host block circuit formed at a first die and configured to communicate with a host device; and
a plurality of media block circuits formed at at least one second die and configured to control a plurality of media devices,
wherein the plurality of media devices are configured to constitute a plurality of channels,
wherein each of the plurality of media block circuits is connected to a corresponding channel of the plurality of channels, and
wherein the host block circuit and the plurality of media block circuits are connected with each other through a chiplet interface.

2. The storage controller of claim 1,
wherein the first die and the at least one second die are formed on a package board.

3. The storage controller of claim 1,
wherein a number of the plurality of channels is two,
wherein a number of the plurality of media block circuits is two,
wherein the first die includes a first silicon substrate, and
wherein the at least one second die includes a second silicon substrate.

4. The storage controller of claim 1,
wherein the first interface includes one of peripheral component interconnect express (PCIe), non-volatile memory express (NVMe), small computer system interface (SCSI), serial attached SCSI (SAS), SCSI express (SCSIe), serial advanced technology attachment (SATA), SATA express (SATAe), computer express link (CXL), and Gen-Z, and
wherein the second interface includes one of a NAND flash interface and a NOR flash interface.

5. The storage controller of claim 1,
wherein a number of the plurality of channels is four,
wherein a number of the plurality of media block circuits is four,
wherein the first die includes a first silicon substrate, and
wherein the at least one second die includes a second silicon substrate.

6. The storage controller of claim 1,
wherein a number of the plurality of channels is eight,
wherein a number of the plurality of media block circuits is eight,
wherein the first die includes a first silicon substrate,
wherein the at least one second die includes two second silicon substrates, and
wherein each of the two second silicon substrates has four media block circuits.

7. The storage controller of claim 1,
wherein a number of the plurality of channels is 16,
wherein a number of the plurality of media block circuits is 16,
wherein the first die includes a first silicon substrate,
wherein the at least one second die includes four second silicon substrates, and
wherein each of the four second silicon substrates has four media block circuits.

8. The storage controller of claim 1, further comprising:
a system bus compatible with the chiplet interface.

9. The storage controller of claim 1,
wherein the host block circuit includes a host interface circuit, and
wherein each of the plurality of media block circuits includes a nonvolatile memory interface circuit.

10. The storage controller of claim 1,
wherein the chiplet interface includes a Universal Chiplet Interconnect Express (UCIe) interface.

11. A storage device comprising:
at least one nonvolatile memory device; and
a controller configured to control the at least one nonvolatile memory device,
wherein the controller includes:
a host interface circuit formed at a first die and connected to a host device; and
a nonvolatile memory interface circuit formed at a second die and connected to the at least one nonvolatile memory device, and
wherein the host interface circuit formed at the first die and the nonvolatile memory interface circuit formed at the second die are configured to communicate with each other using a chiplet interface.

12. The storage device of claim 11,
wherein the controller further includes:
at least one processor formed at the second die and configured to control overall operations of the storage controller;
a buffer memory formed at the second die and configured to temporarily store data which are to be stored in the at least one nonvolatile memory device or which are read from the at least one nonvolatile memory device; and
an error correction circuit formed at the second die and configured to perform error correction on the data.

13. The storage device of claim 12, further comprising:
a system bus formed at the second die,
wherein the system bus is compatible with the chiplet interface, and
wherein the system bus is connected to the at least one processor, the buffer memory, the error correction circuit, and the nonvolatile memory interface circuit.

14. The storage device of claim 11, further comprising:
a volatile memory device,
wherein the controller further includes a volatile memory controller formed at the second die and configured to control an operation of the volatile memory device.

15. The storage device of claim 11,
wherein the at least one nonvolatile memory device is implemented in a stacked package form.

16. A method of operating a storage device, the method comprising:
receiving a write request from a host device by a host interface circuit formed at a first die;
transmitting the write request to a nonvolatile memory interface circuit formed at a second die using a chiplet interface by the host interface circuit; and
outputting a program command corresponding to the write request to at least one nonvolatile memory device by the nonvolatile memory interface circuit.

17. The method of claim 16,
wherein a write request includes write data,
wherein the transmitting of the write request to a nonvolatile memory interface circuit includes:
transmitting the write data to an error correction circuit;
encoding the write data using an error correction code by the error correction circuit; and
transmitting the encoded write data to the nonvolatile memory interface circuit.

18. The method of claim 17,
wherein the error correction circuit is formed at the second die.

19. The method of claim 17,
wherein the error correction circuit is formed at a die different from the first die and the second die.

20. The method of claim 16, further comprising:
receiving write completion information from the at least one nonvolatile memory device by the nonvolatile memory interface circuit; and
transmitting the write completion information to the host interface circuit using the chiplet interface by the nonvolatile memory interface circuit.

21-30. (canceled)
